(19) United States
(12) Patent Application Publication
(10) Pub. No.: US 2025/0257458 A1
(43) Pub. Date: Aug. 14, 2025

(54) METHOD AND APPARATUS FOR ATOMIC LAYER DEPOSITION OF A FLUORIDE LAYER, OPTICAL ELEMENT AND OPTICAL ARRANGEMENT

(71) Applicant: Carl Zeiss SMT GmbH, Oberkochen (DE)

(72) Inventors: Felix LANGE, Nattheim (DE); Alexander WIEGAND, Aalen (DE); Katja SCHICK, Aalen (DE)

(21) Appl. No.: 19/045,745

(22) Filed: Feb. 5, 2025

(30) Foreign Application Priority Data
Feb. 8, 2024 (DE) 102024201149.5

(51) Int. Cl. C23C 16/455; C23C 16/02; C23C 16/28; C23C 16/458; C23C 16/48

(52) U.S. Cl. CPC C23C 16/45536; C23C 16/0236; C23C 16/0281; C23C 16/28; C23C 16/458; C23C 16/482

(57) ABSTRACT

A method of depositing at least one fluoride layer comprises: depositing the fluoride layer on a substrate by photoassisted atomic layer deposition, ALD, in a plurality of ALD cycles. The method comprises irradiating the fluoride layer with UV/VIS light at least in some of the plurality of ALD cycles, such as in all ALD cycles, to anneal at least one potential crystal defect in the fluoride layer. The methods can be performed using an apparatus for atomic layer deposition of at least one fluoride layer, thereby producing an optical element comprising a substrate coated with such a fluoride layer, which can be used in an optical arrangement comprising at least one such optical element.

### CROSS-REFERENCE TO RELATED APPLICATIONS

This application claims priority to German Patent Application No. 10 2024 201 149.5, filed Feb. 8, 2024. The entire disclosure of each of these applications is incorporated by reference herein.

### FIELD

The disclosure relates to a method of depositing a fluoride layer, comprising: depositing the fluoride layer on a substrate by atomic layer deposition, ALD, in a multitude of ALD cycles. The disclosure also relates to an apparatus for atomic layer deposition of at least one fluoride layer, comprising: an ALD chamber having a holder for a substrate, and a gas supply device for supplying a fluorinating active to the ALD chamber. The disclosure additionally relates to an optical element for reflection and/or transmission of radiation in the VUV wavelength range, having a substrate coated with a fluoride layer, and to an optical arrangement for the VUV wavelength range that has at least one such optical element.

In this application, the VUV wavelength range is understood to mean the wavelength range of electromagnetic radiation between 115 nanometers (nm) and 190 nm. The VUV wavelength range is of relevant to microlithography, for example. For instance, radiation in the VUV wavelength range is used in projection exposure apparatuses and wafer or mask inspection apparatuses.

### BACKGROUND

Optical elements having at least one fluoride layer are frequently used in mask inspection apparatuses. Highly reflective optical elements for the VUV wavelength range typically have a fluoride layer, for example, in order to protect an underlying metal layer at which the radiation is reflected against oxidation. Layer stacks composed of different fluorides or fluorides and optionally oxides can additionally be used for reflective coating or antireflective coating of optical elements. However, high radiation intensities as often used in wafer or mask inspection apparatuses and projection exposure apparatuses can lead to degradation of the fluorides and of the optical elements in general, which can shorten the lifetime thereof.

DE 10 2021 201 477 A1 describes a method of operating an optical arrangement comprising at least one optical element including a fluoride. The optical arrangement comprises a regeneration radiation arrangement that provides electromagnetic regeneration radiation having UV wavelengths in order to irradiate the optical element and to bring about the annealing of defects in the fluoride.

The degradation can also be counteracted by way of high-density fluoride layers. High-density fluoride layers can in principle be deposited by a physical vapour deposition (PVD), for example by sputtering deposition. Chemical vapour deposition (CVD), such as atomic layer deposition (ALD), is a particularly promising methodology for deposition of fluoride layers, or generally of layers for optical elements.

In atomic layer deposition, several ALD cycles are performed successively, with deposition of one or more plies of a layer in a respective ALD cycle. An ALD cycle comprises two or more reaction steps, in each of which a self-terminating surface reaction is effected. Typically, in an ALD cycle, in a first reaction step, a first part-reaction with a first precursor takes place, followed in a second reaction step by a second part-reaction with a second precursor, which is also referred to as co-reactant, in order to activate the surface again for the first reaction step. A purge step generally takes place between every two reaction steps.

Atomic layer deposition for deposition of layers of optical elements is described in the literature, including the following documents.

US 2023/0123796 A1 describes an optical component made of crystalline calcium fluoride with a conformal coating that has been deposited by atomic layer deposition. DE 10 2018 211 499 A1 describes a process for producing an optical element for the VUV wavelength range, in which at least two layers are applied to a substrate by atomic layer deposition.

WO 2021/021436 A1 describes an atomic layer deposition method for coating of an optical lens with a magnesium fluoride layer, in which a magnesium oxide layer is first formed and is subsequently converted to the magnesium fluoride layer.

WO 2023/101862 A1 describes protective coatings for aluminium mirrors. For production thereof, an aluminium layer is deposited by a physical deposition process on a glass substrate, a first and second fluorine-containing layer, for example of MgF₂ or AlF₃, are deposited on the aluminium layer by a physical deposition process, and a third fluorine-containing layer is deposited on the second fluorine-containing layer by an atomic layer deposition process. Prior to the deposition of the first fluorine-containing layer, a native aluminium oxide layer may be removed from the surface of the aluminium layer by an atomic layer etching process.

While thermal ALD processes are generally unattractive owing to the elevated temperature in the coating of optical components, particularly ALD processes that are photoassisted or based on use of a plasma can be promising.

U.S. Pat. No. 7,798,096 B2 describes the use of UV light for assisting the deposition of high-k dielectrics via chemical vapour deposition or atomic layer deposition. In that case, the UV light is used to excite or ionize the process gas and thereby to initiate or enhance surface reactions during the deposition.

US 2005/0148206 A1 describes an ALD process in which a layer is supplied with electromagnetic radiation during or after exposure thereof to a second reactant, in order to destabilize unwanted bonds, especially metal-metal bonds, by excitation and convert them to the desired bond form.

US 2017/0058401 A1 describes a photoassisted ALD process for metals in which light is utilized to dissociate a precursor. In order to dissociate the precursor with maximum efficiency, various wavelengths may be supplied.

The article “Photo-Assisted ALD: Process Development and Application Perspectives”, V. Miikkulainen, 2017 ECS Trans. 80 49, states that photoassisted ALD can simplify what is called selective-area ALD, and photoassisted ALD processes for metal oxides and metals are described, in which D₂ lamps inter alia are used.

The article “Atomic layer deposition of aluminum fluoride using Al(CH₃)₃ and SF₆ plasma”, M. F. J. Vos et al., Applied Physics Letters 111, 113105 (2017), describes the deposition of a dense layer of AlF₃ using trimethylaluminium (Al(CH₃)₃) as precursor and a SF₆ plasma as co-reactant at temperatures between 50° C. and 300° C. The article and the supplementary material for this article report extinction coefficients of the deposited layer of AlF₃. The extinction coefficients reported therein for the VUV wavelength range are comparatively high and increase with decreasing deposition temperature, which results in low optical performance of the deposited AlF₃ layers. The idea is expressed in the article that the relatively large extinction coefficient at a deposition temperature of 50° C. is attributable to a greater proportion of sulfur in the environment.

### SUMMARY

The disclosure seeks to provide a method and an apparatus for atomic layer deposition of fluoride layers that have high optical performance, and also an optical element and an optical arrangement comprising such an optical element.

According to a first aspect, the disclosure provides a method of the type specified at the outset, comprising the following additional step: irradiating the fluoride layer with UV/VIS light at least in some of the plurality of ALD cycles, in particular in all ALD cycles, to anneal at least one potential crystal defect in the fluoride layer. The fluoride layer is typically a metal fluoride layer.

The inventors have recognized that photoassisted ALD processes and of plasma ALD processes can result in the deposited fluoride layer being exposed to high-energy photons in the UV and VUV wavelength range during the coating process. This high-energy light typically has the effect that defects (e.g. colour centres) are formed in the fluoride layer. These defects can also arise in the volume of the growing layer and have an adverse effect both on optical performance, i.e. on absorption in the useful wavelength range, in the present case the VUV wavelength range, and on the lifetime of the optical components. These defects can occur at a comparatively low deposition temperature and are the actual cause of the greater extinction coefficients that are described in the above-cited article by M. F. J. Vos.

In order to resolve the technical contradiction between a desirably low deposition temperature in the ALD process on the one hand and defect-free growth of solids on the other hand, the inventors suggest that additional light be supplied for annealing the crystal defects that are typically or potentially formed during the ALD process, for example during a photoassisted ALD process or a plasma ALD process. The irradiation with the UV/VIS radiation for annealing of crystal defects that are typically or potentially formed in the deposition of the fluoride layer can be effected in any of the ALD cycles, but it is also possible that the irradiation is conducted only in some of the ALD cycles, for example in every second, third, fourth, . . . ALD cycle, if this is sufficient to anneal the potential crystal defects in the volume of the fluoride layer.

In the context of this application, UV light is understood to mean electromagnetic radiation in a wavelength range of between 100 nm and 380 nm. In the context of this application, VIS light is understood to mean radiation in a wavelength range of between 380 nm and 830 nm. In the context of this application, UV/VIS light is understood to mean radiation in a wavelength range of between 100 nm and 380 nm (UV light) and/or between 380 nm and 830 nm (VIS light). The UV/VIS wavelength range can be limited further and can lie between 170 nm and 730 nm, for example. The irradiation with UV/VIS light is generally not effected over the entire UV/VIS wavelength range, but rather in one or more selected spectral regions adapted to the crystal defect to be annealed in each case, especially in the form of a colour centre, for example an F centre. A respective spectral region can optionally comprise just a single wavelength, for example if the UV/VIS light is generated by a laser source, for example by an excimer laser.

Suitable wavelengths can be selected, for example, in the manner described in DE 10 2021 203 505 A1, which is incorporated in this application by reference in its entirety. This describes depositing a layer of an ionically bonded solid-state material on a substrate by converting a coating material to the gas phase and depositing the coating material converted to the gas phase on the substrate, wherein the layer is irradiated during the deposition with UV/VIS light in a first spectral region, which at least partly overlaps with an absorption region of at least one (potential) crystal defect in order to instantaneously anneal the (potential) crystal defect formed on deposition of the coating material.

In one variant of the method according to the disclosure, in a first reaction step of a respective ALD cycle, the fluoride layer is exposed to a metallic precursor, where the fluoride layer is optionally not irradiated with UV/VIS light in the first reaction step to anneal the at least one potential crystal defect. The deposited fluoride layer is typically a metal fluoride layer that is deposited with the aid of a metallic precursor. Irradiation with UV/VIS light for annealing of potential crystal defects during the first reaction step is generally unfavourable, one reason being that the metallic precursor can be undesirably excited or dissociated by the UV/VIS light, which has an adverse effect on layer formation.

In a further development of this variant, the metallic precursor is selected from the group comprising: Al(CH₃)₃, AlCl₃, (C₂H₅)₃Al, Mg(thd)₂, Mg(EtCp)₂, Ca(thd)₂, La(thd)₂ and LiHMDS. The metallic precursor is chosen depending on the nature of the fluoride layer that is to be deposited in the ALD process. If it is an AlF₃ layer, it is possible, for example, to use Al(CH₃)₃, i.e. trimethylaluminium (TMA), AlCl₃, i.e. trichloroaluminium, or (C₂H₅)₃Al, i.e. triethylaluminium. If it is an MgF₂ layer, it is possible, for example, to use Mg(thd)₂ or Mg(EtCp)₂, where “thd” is 2,2,6,6-tetramethyl-3,5-heptanedionato and “EtCp” is ethylcyclopentadienyl. The metallic precursor used in the case of a CaF₂ layer may, for example, be Ca(thd)₂, in the case of an LaF₃ layer for example La(thd)₂, and in the case of an LiF layer for example LiHMDS, i.e. lithium hexamethyldisilazide.

In a further variant, the fluoride layer is irradiated with the UV/VIS light to anneal the at least one potential crystal defect during and/or after a second reaction step of a respective ALD cycle in which the fluoride layer is exposed to a reactive fluorine precursor. In this variant, the reactive fluorine precursor is typically generated by exciting a fluorinating active, where the excitation can be effected using a plasma or using electromagnetic radiation, i.e. by light. The inventors have recognized that it can be favourable to conduct the irradiating with the UV/VIS light for annealing of the at least one potential crystal defect, also called “bleaching”, during the second reaction step or in a dedicated bleaching step after the second reaction step. If the bleaching is effected in a dedicated bleaching step, it may be favourable when the fluoride layer is also exposed to a fluorinating active during the additional bleaching step.

In a development of this variant, the reactive fluorine precursor is generated by plasma generation from a fluorinating active. The atomic layer deposition process may be conducted, for example, as described in the article by M. F. J. Vos et al. cited above, which is incorporated in this application by reference in its entirety. In the ALD process described therein, SF₆ gas is used as fluorinating active, from which an inductively coupled plasma is generated in a plasma source and contains, as reactive fluorine precursor or as reactive fluorine species, for example, F, F₂ and SF₄ and SF⁵⁺ ions, and also F⁻ ions. It is likewise stated therein that, in the case of a plasma ALD process, it is also possible to use other fluorinating actives, for example HF or HF-pyridine.

In a further variant, the reactive fluorine precursor is generated by photodissociation from a fluorinating active. In this variant, the fluorinating active is irradiated with light, typically with UV/VUV light having at least one wavelength, the energy of which is at least as great as the dissociation energy of the fluorinating active. The light source used for the photodissociation may, for example, be a deuterium lamp that virtually continuously emits light with a wavelength range between about 115 nm and about 800 nm.

In a further embodiment, the fluorinating active is selected from the group comprising: SF₆, NF₃, HF, HF-pyridine, F₂, NH₄F, CF₄, CHF₃, TiF₄, WF₆, MoF₅, TaF₅. As described above, the fluorinating active, typically in the gas phase, can be activated by photo dissociation or by plasma formation, i.e. converted to a reactive fluorine precursor, in order that the second (partial) step of the reaction in a respective ALD cycle can proceed at the surface of the fluoride layer. As described above, it may be favourable when the irradiation with UV/VIS light, alternatively or additionally to the irradiation in the second reaction step, is effected in a dedicated bleaching step in which the fluoride layer is exposed to a fluorinating active without activation thereof.

In a further variant, the method comprises: irradiating the fluoride layer with light in a third spectral region for photodissociation of the fluorinating active, where the third spectral region is in the useful wavelength range of the optical element formed in the deposition of the fluoride layer, in particular in the VUV wavelength range.

In this variant, the fluorinating active is photodissociated by irradiating the fluoride layer with light in a third spectral region. It has been found to be favourable when the third spectral region is in the useful wavelength range of the optical element, for example in the VUV wavelength range. The third spectral region may optionally comprise only one wavelength, but it may also be a broader spectral region. The light source used for the photodissociation in this case too may be a deuterium lamp, where wavelengths outside the useful wavelength range, for example wavelengths of more than 190 nm, are suppressed by optical filtering. The use of a third spectral region in the useful wavelength range of the optical element means that there is only minor energy input, if any, into the substrate of the optical element in this case on deposition of the fluoride layer.

In a further variant, the fluoride layer is irradiated in a first spectral region to anneal the at least one potential crystal defect with UV/VIS light, where the fluoride layer is optionally irradiated with light in a second spectral region to mobilize atoms on its surface. As described above and in DE 10 2021 203 505 A1, the first spectral region or a suitable wavelength for the annealing of the potential crystal defect depends on the absorption of energy of the crystal defect or on the anion-cation distance in the fluoride layer. For example, in the case of an AlF₃ layer, the first spectral region may be between about 170 nm and 190 nm, and in the case of an MgF₂ layer or an LaF₃ layer at or close to a central wavelength of 260 nm. The fluoride layer may also be irradiated with UV/VIS light in a second spectral region for mobilization of atoms at the surface thereof, as likewise described in DE 10 2021 203 505 A1. The second spectral region may lie, for example, within an energy range between 75% and 100%, such as between 80% and 95%, of a bandgap energy of the fluoride layer. The second spectral range may lie, for example, between 115 nm and 122 nm.

In a development of this variant, the first spectral region is at wavelengths of more than 190 nm. Annealing of crystal defects using UV/VIS light having a first spectral region at wavelengths of more than 190 nm has been found to be favourable.

In one development of this variant, at least two fluoride layers having different metallic constituents are deposited on the substrate, where the first spectral region on irradiation of the fluoride layer is matched to the respective metallic constituent. As described above, the first spectral region for annealing of the at least one potential crystal defect may be selected or matched depending on the metallic constituent of the fluoride layer, which is a metal fluoride layer in this case. It will be apparent that, in this way, it is also possible to deposit more than two fluoride layers, especially layer stacks of more than two fluoride layers.

In a further variant, the method additionally comprises: depositing a metal layer, in particular an aluminium layer, on the substrate prior to introduction of the substrate into an ALD chamber for deposition of the at least one fluoride layer. In this case, the metal layer or aluminium layer is deposited by an external deposition process outside the ALD chamber that is not atomic layer deposition, for example by a thermal evaporation process. It is also possible to externally deposit one or more further fluoride layers on the metal layer, i.e. before the substrate is introduced into the ALD chamber. These fluoride layers are also deposited by a deposition process that is not atomic layer deposition.

In a further development of this variant, the method comprises: removing an aluminium oxyhydroxide layer from the aluminium layer deposited on the substrate by atomic layer etching in the ALD chamber. The external deposition of the aluminium layer typically forms an AlₓO_{y} layer, or more generally an AlₓO_{y}OH_{z} layer, of generally about 3 nm in thickness on the surface of the aluminium layer. In order to remove this, an atomic layer etching process may be conducted in the ALD chamber before the at least one fluoride layer is deposited by the atomic layer deposition process. In an atomic layer etching process, similarly to an atomic layer deposition process, individual atomic layers are removed cyclically in two separate self-limiting part-reactions. For this purpose, suitable reactive gases can be used in the two-part-reactions or reaction steps.

In an alternative development, the method comprises: converting an aluminium oxyhydroxide layer formed on the aluminium layer to an aluminium fluoride layer by fluorinating the aluminium oxyhydroxide layer in the ALD chamber. For the fluorination, one of the fluorinating actives described above is typically used, which is converted to active fluorine species by photodissociation or using a plasma, as described above in connection with the ALD process. After conversion to the aluminium fluoride layer, in the manner described above, at least one fluoride layer is deposited by atomic layer deposition on the substrate or on the aluminium fluoride layer formed by the conversion.

In principle, it is possible also to conduct the fluorination described further above in connection with the aluminium oxyhydroxide layer on the fluoride layer deposited by atomic layer deposition in the ALD chamber in order to undertake post-fluorination or refluorination of the deposited fluoride layer. This may be favourable, for example, if a layer of an oxyfluoride/hydroxyfluoride has formed on the surface of the fluoride layer. For the fluorination, the surface of the fluoride layer is exposed to a fluorinating active.

This is typically converted by photodissociation using UV/VIS radiation or using a plasma to active fluorine species that bring about refluorination of the fluoride layer.

It is possible to heat the substrate during the performance of the ALD process in the ALD chamber at least in some of the plurality of ALD cycles and/or during the refluorination.

A further aspect of the disclosure relates to an apparatus for atomic layer deposition of the type specified at the outset, further comprising at least one UV/VIS light source for irradiation of the fluoride layer with UV/VIS light, in order to anneal at least one potential crystal defect of the fluoride layer.

With regard to the properties achieved with the apparatus and its embodiments described below, reference should be made to the above explanations regarding the method and its variants. The UV/VIS light source may be a light source designed for emitting UV light (UV light source) or for emitting VIS light (VIS light source). It is also possible for the light source to be designed for emitting both UV light and VIS light.

It is possible that the at least one UV/VIS light source is spectrally tunable. Tunable UV/VIS light sources are particularly well-suited to the present application since their spectrum can easily be adapted to different potential crystal defects and different materials. Suitable tunable UV/VIS light sources are wideband light sources, for example, which enable downstream wavelength selection. A suitable example for UV light may be a D₂ gas discharge lamp with downstream wavelength selection. A plasma light source can also be used for this purpose.

The ALD chamber may be sealed in a gas-tight manner. The inside of the ALD chamber is stable to the fluorinating active or the reactive fluorine precursor and its conversion products. The conversion products of the fluorinating active mean the fluorine species and the chemical compounds formed therefrom (for example HF). Stability should be understood in particular in the sense that a passivating layer is formed on the inside of the ALD chamber. For example, there is to be no formation of volatile fluorine compounds that can be precipitated on the optical element or on the substrate. The ALD chamber, especially the inside thereof, can be manufactured, for example, at least partly from a metallic material which should typically be free of Cr and Ti, in order to prevent corrosion. The ALD chamber may for example have been manufactured from Monel steel. The inside of the ALD chamber may also have a fluorine-stable coating in order to prevent corrosion. Such a coating can be applied by a galvanic process. Suitable materials include for example NiP, Pt, Ni, Cu or Ru/Rh mixtures. If the apparatus has a plasma source (see below), for example, in general no W, Si and no Cr-containing metals should be used in the ALD chamber.

In one embodiment, the apparatus comprises an activation device for generation of a reactive fluorine precursor from the fluorinating active, having a plasma source and/or a UV/VIS light source for photodissociation of the fluorinating active. As described above, in the second reaction step of the ALD cycle, the surface of the growing fluoride layer is exposed to a reactive fluorine precursor which is generated from the fluorinating active. For this purpose, the fluorinating active may be supplied to a plasma source and/or irradiated by a UV/VIS light source that generates UV/VIS light with an energy at least twice as great as the dissociation energy of the fluorinating active.

It will be apparent that the apparatus may also have further components typical of ALD systems, for example metering devices for the metallic precursor including valves and mixer assemblies, metering devices for the fluorinating active including valves and mixer assemblies, metering devices for purge gas or for an inert gas, vacuum technology for creation of a vacuum in the ALD chamber, vacuum locks, etc. For example, the apparatus may also have stops for plasma shadowing and/or for plasma forming. It can be also favourable when the apparatus has a device for optical monitoring of the ALD process, for example by in situ ellipsometry. If a plasma source is used to create the reactive fluorine precursor, the ALD chamber may also have a sensor system for monitoring the plasma in the plasma source.

A further aspect of the disclosure relates to an optical element of the type specified at the outset, in which the fluoride layer has been deposited by the method described above and/or by the apparatus described above. It will be apparent that the optical element may also have two or more fluoride layers that have been deposited by the ALD process described above or the corresponding apparatus. The optical element may additionally also have one or more fluoride layers or other layers that have not been deposited by atomic layer deposition, for example metallic layers.

The optical element may be a transmissive optical element, for example the laser chamber window of an excimer laser. In this case, the outside of the laser chamber window is generally coated with a high-density fluoride layer. However, the optical element may also be a reflective optical element, for example a mirror serving for deflecting or focusing radiation in the VUV wavelength range, or a beam splitter serving both for transmitting and for reflecting radiation in the VUV wavelength range.

A further aspect of the disclosure relates to an optical arrangement for the VUV wavelength range, such as a VUV lithography apparatus or a wafer inspection system, comprising at least one optical element as described above. The optical arrangement may, for example, be a (VUV) lithography system, a wafer or mask inspection system, a laser system, etc.

Further features of the disclosure will be apparent from the description of working examples of the disclosure that follows, with reference to the figures of the drawings, which show certain details of the disclosure, and from the claims. The individual features can be implemented individually in their own right or collectively in any combination in a variant of the disclosure.

Working examples are shown in the schematic drawing and are elucidated in the description that follows.

### BRIEF DESCRIPTION OF THE DRAWINGS

The figures show:

FIG. 1 a schematic diagram of an apparatus for atomic layer deposition of fluoride layers on a substrate, having two UV light sources for emission of UV light and an excitation device for excitation of a fluorinating active,

FIG. 2 a flow diagram of an ALD process for deposition of a fluoride layer on the substrate in the apparatus of FIG. 1,

FIGS. 3A, 3B flow diagrams of two variants of a photo-ALD process for deposition of the fluoride layer,

FIGS. 4A, 4B flow diagrams of two variants of a plasma-ALD process for deposition of the fluoride layer,

FIG. 5 a flow diagram of a process for coating an optical element, in which further layers are deposited in addition to the fluoride layer deposited in the ALD process,

FIG. 6 a flow diagram of a coating process in which an oxyhydroxide layer is removed in an ALD chamber prior to deposition of the fluoride layer,

FIG. 7 a flow diagram of an ALD process for deposition of multiple different fluoride layers,

FIG. 8 a schematic diagram of an optical arrangement for the VUV wavelength range in the form of a VUV lithography apparatus,

FIG. 9 a schematic diagram of an optical arrangement for the VUV wavelength range in the form of a wafer inspection system, and

FIG. 10 a schematic diagram of an optical element in the form of a laser chamber window.

### DETAILED DESCRIPTION

In the description of the drawings that follows, identical reference signs are used for components that are the same or have the same function.

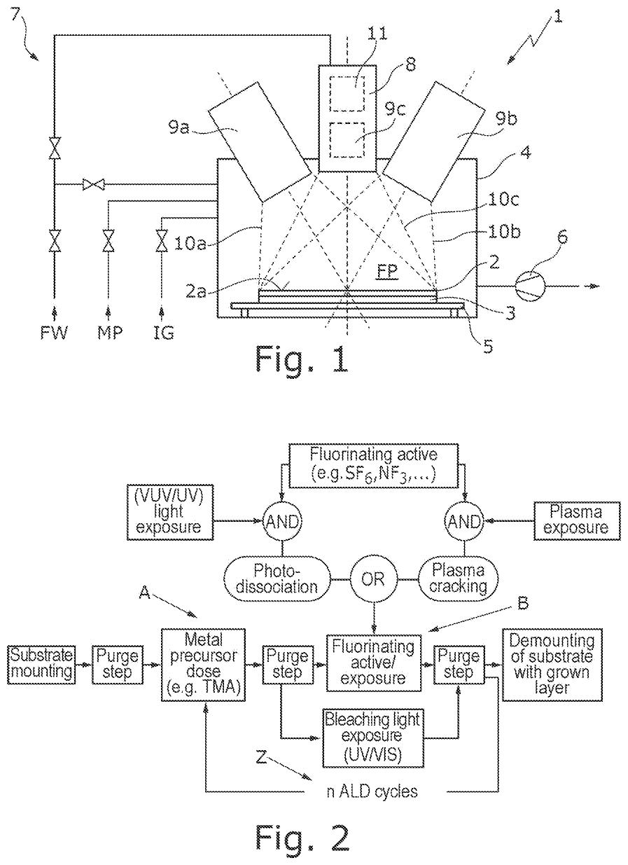

FIG. 1 shows an apparatus 1 for atomic layer deposition of one or more fluoride layers 2 on a substrate 3. For this purpose, the apparatus 1 comprises an ALD chamber 4 in the form of a vacuum chamber, in which is mounted a mount 5 (manipulator) for the substrate 3 in the form of a rotary table. An electrical potential (bias) can be applied to the mount 5, for example in order to accelerate ions from a plasma in the direction of the substrate 3. The mount 5 may also be heated with the aid of a heating device, which is not shown pictorially. A vacuum pump 6 serves to generate a vacuum in an interior of the ALD chamber 4.

The apparatus 1 also has a gas supply device 7 designed to supply a gaseous fluorinating active FW, a gaseous metallic precursor MP and a purge gas or inert gas IG to the ALD chamber 4, and having multiple gas inlets for this purpose. The gas supply device 7 additionally has a valve arrangement or metering arrangement that enables controlled supply of the gaseous fluorinating active FW, the gaseous metallic precursor MP and the inert gas IG to the interior of the ALD chamber 4. The fluorinating active FW may also be supplied to an activation device 8, and thereby to the interior of the ALD chamber 4, as described in detail further down.

The metallic precursor MP supplied from a gas reservoir may, for example, be Al(CH₃)₃, AlCl₃, (C₂H₅)₃Al, Mg(thd)₂, Mg(EtCp)₂, Ca(thd)₂, La(thd)₂ or LiHMDS. The fluorinating active FW is chosen depending on the metallic constituent of the fluoride layer 2, which, in the example shown, is a metal fluoride layer. The fluorinating actives FW described here are capable of depositing a fluoride layer 2 in the form of an AlF₃ layer, an MgF₂ layer or an LaF₃ layer in an ALD process. In the example shown, trimethylaluminium, i.e. Al(CH₃)₃, is used as the metallic precursor MP.

The inert gas IG may, for example, be a noble gas, for example argon, which may serve purposes including ventilation of the ALD chamber 4 prior to opening and establishment of a pressure in the interior of the ALD chamber 4, and in particular may serve as purge gas for purging of the interior of the ALD chamber 4 between reaction steps A and B of the ALD process; cf. FIG. 2.

The fluorinating active FW may be, for example: SF₆, NF₃, HF, HF-pyridine, F₂, NH₄F, CF₄, CHF₃, TiF₄, WF₆, MoF₅ or TaF₅. In the example shown, the fluorinating active used is gaseous SF₆. For the performance of a (partial) reaction step of the ALD process, it is desirable to use the fluorinating active FW to create a reactive fluorine precursor FP to which the surface of the fluoride layer 2 or substrate 3 is exposed. This purpose is served by the activation device 8.

For this purpose, the activation device 8 shown in FIG. 1 has a (third) light source 9c in the form of a photodissociation light source for photodissociation of the fluorinating active FW, and a plasma source 11. If the fluorinating active FW is activated by the UV light source 9c, it is introduced directly into the interior of the ALD chamber 4 via a gas inlet of the gas supply device 7. In this case, the activation is effected by photodissociation of the fluorinating active FW by light 10c which is generated by the third light source 9c. The light 10c generated by the third light source 9c has at least one wavelength here that has greater photon energy than the dissociation energy of the fluorinating active FW. The third light source 9c, or the light 10c generated thereby, is thus matched to the fluorinating active FW used. In the example shown, the light 10c from the third light source 9c is radiated onto the fluoride layer 2. The light 10c of the third light source is light 10c of a third spectral region within the useful wavelength range of an optical element, which is formed on deposition of the fluoride layer 2 onto the substrate 3. In the example shown, the third spectral region is within the VUV wavelength range.

If the reactive fluorine precursor FP is generated from the fluorinating active FW by the formation of a plasma, the fluorinating active FW is supplied to the plasma source 11, is activated thereby and forms the reactive fluorine precursor FP, which may include, for example, fluorine radicals or fluorine in an excited electron state. It will be apparent that the activation device 8 need not necessarily include both the plasma source 11 and the photodissociation light source 9c: In general, one of these two sources is sufficient to generate the reactive fluorine precursor FP.

The apparatus 1 shown in FIG. 1 also has a first and second UV light source 9a, 9b, which serve to generate UV light 10a, 10b incident on the surface 2a of the fluoride layer 2. In the example shown in FIG. 1, the first UV light source 9a is designed to emit UV light 10a in a first spectral range which serves to anneal potential crystal defects during deposition of the fluoride layer 2 in the atomic layer deposition process. The first spectral region may be at wavelengths of more than 190 nm. The second UV light source 9b is designed to emit UV light 10b in a second spectral range which serves to mobilize atoms at the surface 2a of the fluorine layer 2. The two spectral regions are not shown pictorially and are selected depending on the deposited material, where the selection may be made, for example, in the manner described in DE 10 2021 203 505 A1, cited at the outset.

In a departure from the illustration in FIG. 1, the apparatus 1 may have a single UV light source which emits UV light 10a, 10b both in the first spectral range and in the second spectral range. The apparatus may also have only the first UV light source 9a, which emits UV light 10a in the first spectral range. The apparatus 1 may also have more than two UV light sources 9a, 9b.

In the example shown, both the first UV light source 9a and the second UV light source 9b are designed to respectively emit UV light 10a, 10b in a fixed first and second spectral range. However, it is also possible for the first and/or the second UV light source 9a, 9b to be tunable in order to be able to set or tune the first and/or the second spectral range. In the example shown in FIG. 1, the first UV light source 9a is an excimer laser having a wavelength of 193 nm, and the second UV light source 9b is a D₂ lamp that emits light e.g. in a wavelength range from 115 nm to 122 nm.

Alternatively, one or both light sources 9a, 9b may be designed to generate light in the visible wavelength region (VIS light). In this case, the light sources 9a, 9b may be designed to respectively emit VIS light in a defined first and second spectral range, or the light sources 9a, 9b may be designed to be tunable. Moreover, a single VIS light source may be designed to generate VIS light both in the first spectral range and in the second spectral range. It is also possible to provide one or more UV light sources and one or more VIS light sources.

There follows a description of the method of atomic layer deposition of a fluoride layer, more specifically an AlF₃ layer, in the apparatus 1 from FIG. 1 with reference to the flow diagram shown in FIG. 2. In the method, in a first step, the substrate 3, for example in the form of a glass substrate or crystal, is secured on the mount 5 and a purge step is conducted, and the ALD chamber 4 is evacuated. Subsequently, a first (partial) reaction step A of an ALD cycle Z is conducted, in which the substrate 3 or the surface of the already deposited portion of the fluoride layer 2 is exposed to the metallic precursor MP, and a first surface reaction of the ALD process proceeds on the surface of the fluoride layer 2. After a subsequent purge step, in which residues of the metallic precursor MP and volatile reaction products from the first reaction step A are pumped out of the interior of the ALB chamber 4, a second (partial) reaction step B of the ALD cycle Z is conducted.

In the second reaction step B, the surface 2a of the fluoride layer 2 is exposed to the reactive fluorine precursor FP. This is generated in the manner described in association with FIG. 1, either by photodissociation or by formation of a plasma from the fluorinating active, which is SF₆ in the example disclosed. The surface reactions that proceed in the two reaction steps A, B are described in the article cited at the outset by M. F. J. Vos et al. The two reaction steps A, B and the respectively subsequent purge steps form an ALD cycle Z in which one or more layers of AlF₃ are deposited. The ALD cycle Z is repeated n times until the fluoride layer 2 has its predetermined thickness. The number n of ALD cycles Z, depending on the thickness of the fluoride layer 2, may, for example, be between about 10 and 500. After the fluoride layer 2 has been grown on with the desired thickness, the substrate 3 is removed from the mount and from the ALD chamber 4.

As likewise apparent in FIG. 2, in the second reaction step B, the substrate 3 or surface 2a of the fluoride layer 2 is exposed to the UV light 10a from the first UV light source 9a in order to anneal at least one potential crystal defect in the fluoride layer 2, as described above in association with FIG. 1.

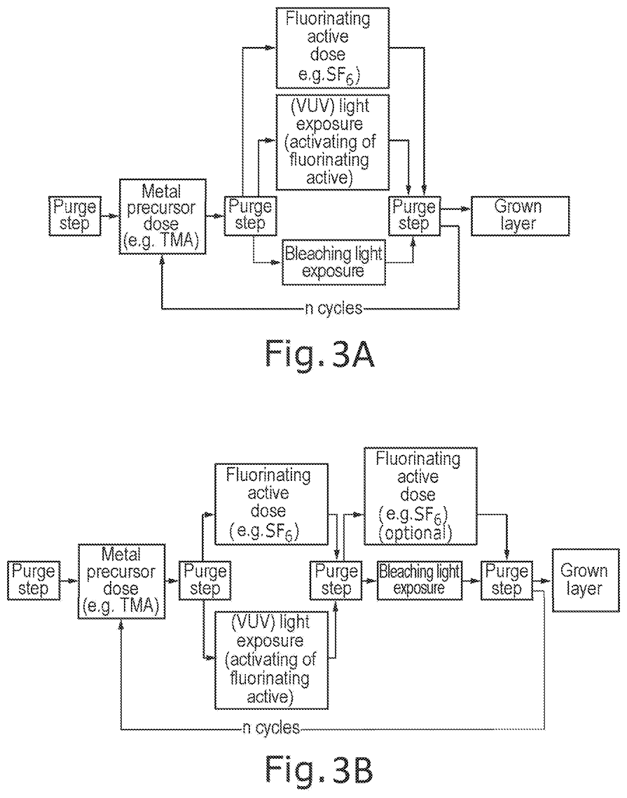

FIG. 3A, 3B show two variants of a photo-ALD process for deposition of the fluoride layer 2, of which the first variant shown in FIG. 3A corresponds to the variant shown in FIG. 2 in which the fluorinating active FW is activated by photodissociation. In the variant shown in FIG. 3B, in addition to the irradiation of the fluoride layer 2 with UV light 10a in the second reaction step B, a bleaching step is conducted in a further, subsequent process step of a respective ALD cycle Z, in which the surface 2a of the fluoride layer 2 is likewise irradiated with UV light 10a in order to anneal potential crystal defects in the fluoride layer 2. Alternatively, the bleaching can be conducted solely after the second reaction step B. As likewise shown in FIG. 3B, in the bleaching step, a fluorinating active FW may additionally be supplied in the interior of the ALD chamber 4 in order to bring about refluorination of the fluoride layer 2, for example when a layer of an oxyfluoride/hydroxyfluoride has formed on the surface 2a of the fluoride layer 2.

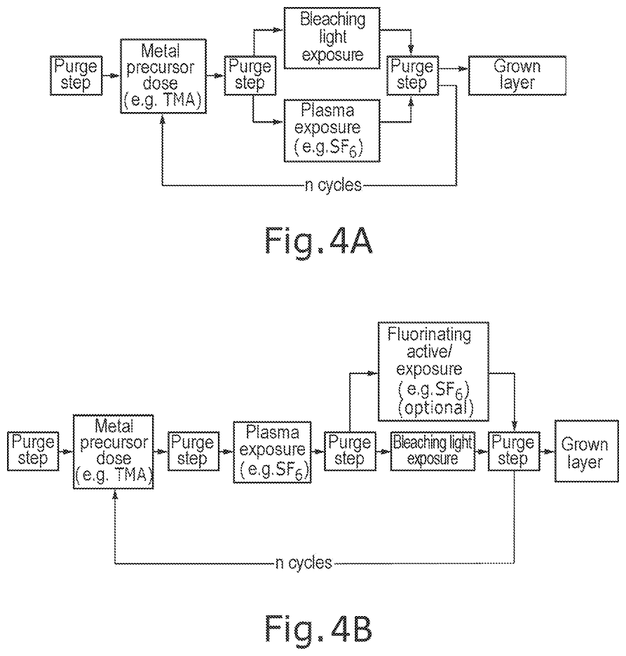

FIG. 4A, 4B show two variants of a plasma ALD process for deposition of the fluoride layer 2, of which the first variant shown in FIG. 4A corresponds to the variant shown in FIG. 2 in which the fluorinating active FW is activated by a plasma or plasma cracking to form the reactive fluorine precursor FP. In FIG. 4B, analogously to FIG. 3B, in a dedicated bleaching step conducted after the second reaction step B, the surface 2a of the fluoride layer 2 is irradiated with UV/VIS light 10a. Unlike in FIG. 3B, in the variant shown in FIG. 4B, no bleaching is conducted during the second reaction step B. But it will be apparent that this is also possible in the plasma ALD process described in FIG. 4B.

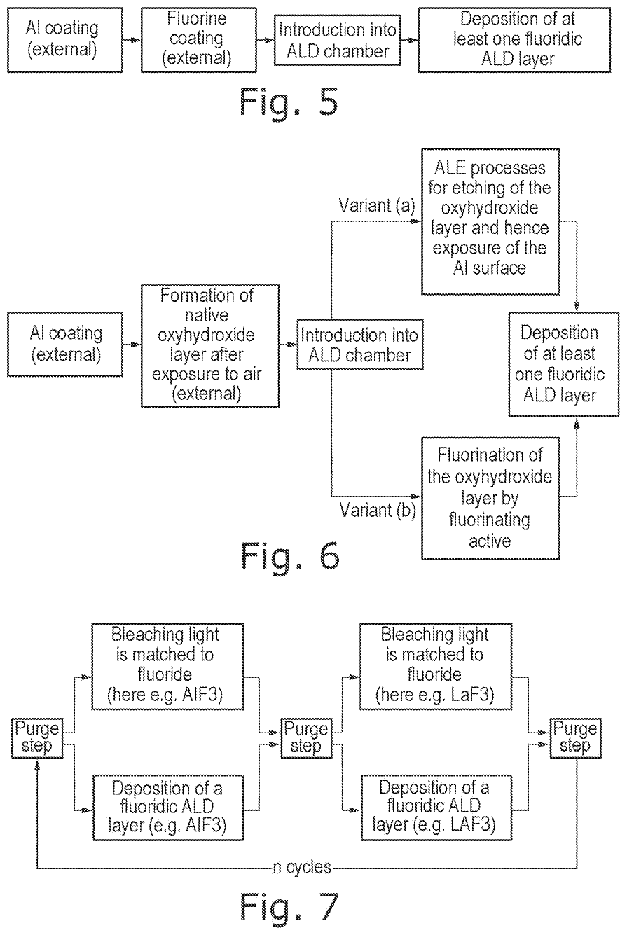

For the production of an optical element, it is typically not only the fluoride layer 2 that is deposited on the substrate 3, but generally further layers. FIG. 5 shows a flow diagram of a method in which, in two preceding steps, first an aluminium layer and subsequently a fluoride layer or fluoride coating are deposited on the substrate 3, before the coated substrate 3 is introduced into the ALD chamber 4, and a fluoride layer 2 is deposited on the coated substrate 3 by atomic layer deposition in the manner described above. The deposition of the aluminium layer and of the fluoride layer prior to introduction into the ALD chamber 4 is effected not by atomic layer deposition but rather, for example, by a thermal evaporation process.

FIG. 6 shows a process sequence analogous to FIG. 5, in which, after deposition of the aluminium layer under ambient air, a native thin AlₓO_{y} layer or more generally an AlₓO_{y}OH_{z} layer has formed on the surface of the aluminium layer. In order to remove this, an atomic layer etching process may be conducted in the ALD chamber 4 before the at least one fluoride layer 2 is deposited by the atomic layer deposition process (variant (a) in FIG. 6). The apparatus 1 in this case is designed not just for atomic layer deposition but additionally also for atomic layer etching.

Alternatively, the AlₓO_{y}OH₂ layer may be removed from the surface of the aluminium oxide layer by converting it to an aluminium fluoride layer (variant (b) in FIG. 6). The conversion is accomplished using a fluorinating active FW, to which the surface of the aluminium layer is exposed and active fluorine species are generated therefrom by photo dissociation or by a plasma, as described above in association with the ALD process. After conversion to the aluminium fluoride layer, in the manner described above, at least one fluoride layer 2 may be deposited by atomic layer deposition on the substrate 3, or more specifically on the aluminium fluoride layer formed by the conversion.

It is also possible to conduct the fluorination described above in connection with the aluminium oxyhydroxide layer on the fluoride layer deposited by atomic layer deposition in the ALD chamber 4 in order to undertake post-fluorination or refluorination of the deposited fluoride layer 2. This may be favourable, for example, if a layer of an oxyfluoride/hydroxyfluoride has formed on the surface of the fluoride layer 2. For the fluorination, the surface 2a of the fluoride layer 2 is exposed to a fluorinating active FW. This is typically converted by photodissociation using UV/VIS light 10c or using a plasma to active fluorine species that bring about refluorination of the fluoride layer 2.

FIG. 7 shows a process sequence in the deposition of multiple dielectric functional fluoride layers that are applied alternately to the substrate 3 in order to create a functional coating, for example in the form of a reflective or antireflective dielectric coating, which in the example shown has a number n of alternating layers of AlF₃ and LaF₃. In the deposition of a respective fluoride layer 2, the bleaching light, or more specifically the spectral range of the UV light 10ₐ emitted by the first UV light source 9a, is matched to the metallic material of the fluoride layer 2 that is to be deposited. More specifically, in the example shown, the first spectral range is switched from a wavelength range between about 170 nm and 190 nm for atomic layer deposition of AlF₃ to a wavelength of about 260 nm for atomic layer deposition of MgF₂.

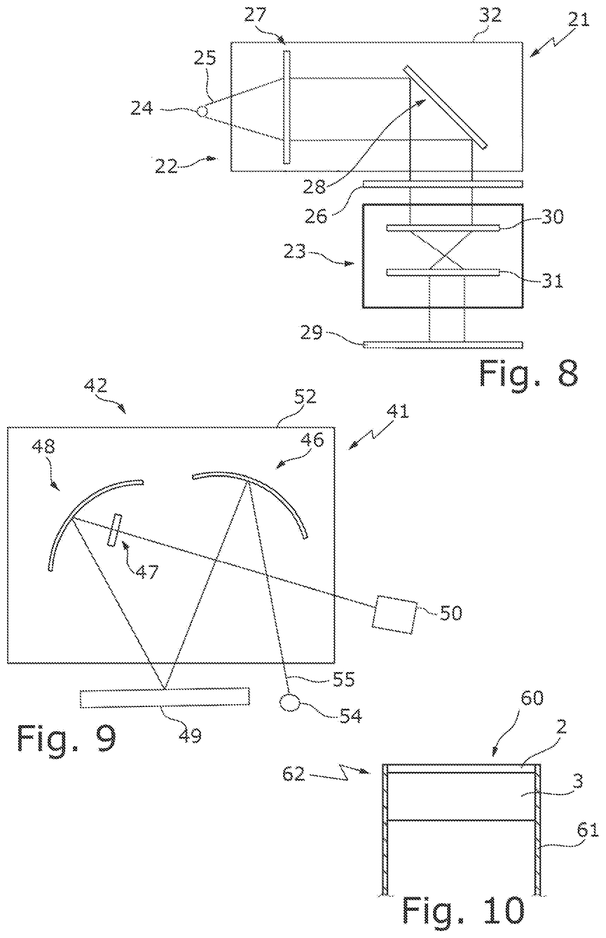

FIG. 8 shows an optical arrangement for the VUV wavelength range in the form of a VUV lithography apparatus 21. The VUV lithography apparatus 21 comprises two optical systems, namely an illumination system 22 and a projection system 23. The VUV lithography apparatus 21 additionally has a radiation source 24, which may be an excimer laser, for example.

The radiation 25 emitted by the radiation source 24 is conditioned with the aid of the illumination system 22 such that a mask 26, also called a reticle, is illuminated thereby. In the example shown, the illumination system 22 has a housing 32, in which there are disposed both transmissive and reflective optical elements. In a representative manner, the illustration shows a transmissive optical element 27, which focuses the radiation 25, and a reflective optical element 28, which deflects the radiation.

The mask 26 has, on its surface, a structure which is transferred to an optical element 29 to be exposed, for example a wafer, with the aid of the projection system 23 for the purpose of producing semiconductor components. In the example shown, the mask 26 is designed as a transmissive optical element. In alternative embodiments, the mask 26 can also be designed as a reflective optical element.

The projection system 23 has at least one transmissive optical element in the example shown. The example shown illustrates, in a representative manner, two transmissive optical elements 30, 31, which serve, for example, to reduce the structures on the mask 26 to the size desired for the exposure of the wafer 29.

Both in the illumination system 22 and in the projection system 23, a wide variety of transmissive, reflective or other optical elements can be combined with one another as desired, including in a more complex manner. Optical arrangements without transmissive optical elements can also be used for VUV lithography.

FIG. 9 shows an optical arrangement for the VUV wavelength range in the form of a wafer inspection system 41, but a mask inspection system may also be involved. The wafer inspection system 41 has an optical system 42 with a radiation source 54, from which radiation 55 is directed onto a wafer 49 via the optical system 42. For this purpose, the radiation 55 is reflected onto the wafer 49 by a concave mirror 46. In the case of a mask inspection system, it would be possible to replace the wafer 49 with a mask to be examined. The radiation reflected, diffracted and/or refracted by the wafer 49 is directed onto a detector 50 for further evaluation by a further concave mirror 48, which is likewise associated with the optical system 42, via a transmissive optical element 47. The wafer inspection system 41 additionally has a housing 52, in which there are disposed the two mirrors 46, 48 and the transmissive optical element 47. The radiation source 54 may, for example, be exactly one radiation source or a combination of a plurality of individual radiation sources in order to provide a substantially continuous radiation spectrum. In modifications, one or more narrowband radiation sources 54 can also be used.

At least one of the optical elements 27, 28, 30, 31 of the VUV lithography apparatus 21 shown in FIG. 8 and at least one of the optical elements 46, 47, 48 of the wafer inspection system 41 shown in FIG. 9 are designed here as described above. They are thus coated with at least one fluoride layer 2, where the at least one fluoride layer 2 has been deposited by the method described above and/or via the apparatus 1 described above.

FIG. 10 shows an optical element for transmitting radiation in the VUV wavelength range in the form of a laser chamber window 60 of a laser chamber 61 of an excimer laser 62. The laser beam emitted by the excimer laser 62 passes to the outside through the laser chamber window 60. The exterior of the laser chamber window 60 is coated with a fluoride layer 2 which has been deposited by the method described above and/or via the apparatus 1 described above. The fluoride layer 2 was irradiated with UV/VIS light 10a during atomic layer deposition to anneal potential crystal defects and therefore simultaneously has a high density and a low extinction coefficient. Sealing with such a layer 2 counteracts degradation of the laser chamber window 60 and thus prolongs the lifetime thereof.

What is claimed is:

1. A method, comprising:
depositing a fluoride layer on a substrate using photoassisted atomic layer deposition (ALD) in a plurality of ALD cycles,
wherein, for at least some of the ALD cycles, the method comprises irradiating the fluoride layer with UV/VIS light to anneal a potential crystal defect in the fluoride layer.

2. The method of claim 1, comprising, for each of the ALD cycles, irradiating the fluoride layer with UV/VIS light to anneal a potential crystal defect in the fluoride layer.

3. The method of claim 1, wherein, in a first reaction step of a respective ALD cycle, the fluoride layer is exposed to a metallic precursor.

4. The method of claim 3, wherein, during the first reaction step of the respective ALD cycle, the fluoride layer is not irradiated with UV/VIS light.

5. The method of claim 3, wherein the metallic precursor comprises a member selected from the group consisting of Al(CH₃)₃, AlCl₃, (C₂H₅)₃Al, Mg(thd)₂, Mg(EtCp)₂, Ca(thd)₂, La(thd)₂, and LiHMDS.

6. The method of claim 3, wherein:
in a second reaction step of a respective ALD cycle, the fluoride layer is exposed to a reactive fluorine precursor; and
the fluoride layer is irradiated with the UV/VIS light to anneal the potential crystal defect during and/or after the second reaction step.

7. The method of claim 6, wherein the reactive fluorine precursor is generated by photodissociation from a fluorinating active.

8. The method of claim 7, wherein the fluorinating active comprises a member selected from the group consisting of SF₆, NF₃, HF, HF-pyridine, F₂, NH₄F, CF₄, CHF₃, TiF₄, WF₆, MoF₅, and TaF₅.

9. The method of claim 6, further comprising irradiating the fluoride layer with light in a third spectral region to photodissociate the fluorinating active, wherein the third spectral region is in a useful wavelength range of an optical element formed during the deposition of the at least one fluoride layer.

10. The method of claim 6, further comprising irradiating the fluoride layer with VUV light to photodissociate the fluorinating active.

11. The method of claim 1, wherein:
in a reaction step of a respective ALD cycle, the fluoride layer is exposed to a reactive fluorine precursor; and
the fluoride layer is irradiated with the UV/VIS light to anneal the potential crystal defect during and/or after the reaction step.

12. The method of claim 1, comprising irradiating the fluoride layer with light in a first spectral region to anneal the crystal defect, and the first spectral region comprises the UV/VIS wavelength range.

13. The method of claim 12, comprising irradiating the fluoride layer with light in a second spectral region to mobilize atoms on its surface, wherein the second spectral region is different from the first spectral region.

14. The method of claim 12, wherein the first spectral region is at wavelengths of more than 190 nm.

15. The method of claim 12, wherein at least two fluoride layers having different metallic constituents are deposited on the substrate, and the first spectral region on irradiation of a respective fluoride layer is matched to the respective metallic constituent of the fluoride layer.

16. The method of claim 1, comprising:
i) depositing a metal layer on the substrate;
ii) after i) disposing the substrate in an ALD chamber; and
iii) after ii), depositing the fluoride layer on the substrate.

17. The method of claim 16, wherein the metal layer comprises an aluminum layer.

18. The method of claim 17, further comprising, after ii), removing an aluminium oxyhydroxide layer from the aluminium layer by atomic layer etching in the ALD chamber.

19. The method of claim 18, wherein removing the aluminium oxyhydroxide layer comprises fluorinating the aluminium oxyhydroxide layer to convert the aluminium oxyhydroxide layer to an aluminium fluoride layer in the ALD chamber.

20. The method of claim 1, wherein the fluoride layer is a fluoride layer of an optical element.

21. The method of claim 20, wherein the optical element is in a VUV lithography apparatus or a wafer inspection system.

22. An apparatus configured for atomic layer deposition (ALD) of a fluoride layer, comprising:
an ALD chamber comprising a holder configured to hold a substrate;
a gas supply device configured to supply a fluorinating active to the ALD chamber; and
a UV/VIS light source configured to irradiate the fluoride layer with UV/VIS light to anneal a potential crystal defect of the fluoride layer.

23. The apparatus of claim 22, further comprising an activation device configured to generate a reactive fluorine precursor from the fluorinating active, wherein the activation device comprises a UV/VIS light source configured to dissociate the fluorinating active.
